(19) United States
(12) Patent Application Publication
(10) Pub. No.: US 2017/0053992 A1
(43) Pub. Date: Feb. 23, 2017

(54) METHOD OF MANUFACTURING A SEMICONDUCTOR DEVICE AND SEMICONDUCTOR DEVICE

(71) Applicant: Toyota Jidosha Kabushiki Kaisha, Toyota-shi (JP)

(72) Inventors: Masakazu Okada, Toyota-shi (JP); Sachiko Aoi, Nagakute-shi (JP)

(21) Appl. No.: 15/238,180

(22) Filed: Aug. 16, 2016

(30) Foreign Application Priority Data
Aug. 21, 2015 (JP) 2015-164080

(51) Int. Cl. H01L 29/423; H01L 29/51; H01L 21/311; H01L 21/02; H01L 21/04; H01L 21/28

(52) U.S. Cl. CPC H01L 29/4236; H01L 21/049; H01L 21/28238; H01L 21/31116; H01L 21/02329; H01L 21/31111; H01L 29/42364; H01L 29/515; H01L 21/02362; H01L 29/7813

(57) ABSTRACT

A method of manufacturing a semiconductor device includes forming a cured portion by heating a semiconductor substrate in a non-oxidizing atmosphere to cure a front surface of a first insulation material that was not removed in a first-etching and remains in a deep side of the trench; forming a cavity in the trench on a deeper side of the cured portion by making an etchant enter into the trench from an interface to the deeper side to perform a second-etching and removing the first insulation material remaining in the deeper side of the cured portion, the interface being present between portions of the first insulation material that have been grown from side surfaces of the trench, wherein an opening is formed at the interface by the second-etching; and closing the opening at the interface with a second insulation material.

### CROSS-REFERENCE TO RELATED APPLICATION

This application claims priority to Japanese Patent Application No. 2015-164080 filed on Aug. 21, 2015, the contents of which are hereby incorporated by reference into the present application.

### TECHNICAL FIELD

The present application relate to a method of manufacturing a semiconductor device and a semiconductor device.

### BACKGROUND ART

A technique that forms a cavity (that is, a hollow) inside a semiconductor substrate to improve characteristics of a semiconductor device is known. For example, there is a known technique that allows a cavity to remain within an insulator upon filling the insulator to an inside of a trench that insulates and separates a plurality of element regions formed in the semiconductor substrate. When the cavity is present within the insulator, its insulation property is increased than in a case where no cavity is present.

Further, in a semiconductor device in which a gate electrode is provided within a trench, a voltage resistance of the semiconductor device can be increased by enlarging a thickness of a gate insulating film provided between a bottom surface of the trench and a bottom surface of the Gate electrode. If a cavity can be formed within the thick gate insulating film, the effect of improving the voltage resistance can be enhanced.

A method of forming a cavity in a trench is disclosed in Japanese Patent Application Publication No. 2006-49828. In this method, an oxide film is formed on a front surface of a semiconductor substrate, an opening is formed in a part of the oxide film, a trench is formed by etching the semiconductor substrate anisotropically from the opening, further widening a width of the tenth by an isotropic etching, and then growing an insulating film. The insulating film growing from a side surface of the oxide film defining the opening closes the opening before when the trench is closed by the insulating film growing from an inner surface of the trench. Due to this, a cavity remains present within the trench.

### SUMMARY

In the cavity forming method as above, a height of an upper end of the cavity remaining in the trench cannot be adjusted, and it is always fixed to be in a vicinity of the front surface of the semiconductor substrate. For example, a configuration in which the cavity remains present on a deep side of the trench and an insulation material or a conductive material is filled on a front surface side of the trench cannot be achieved. For example, no cavity can be formed inside a gate insulating film that is provided between a bottom surface of the trench and a bottom surface of the gate electrode.

In the present disclosure, a technique that allows a cavity to remain present in a trench, which can adjust a height of an upper end of the cavity (distance from a front surface of a semiconductor substrate to the cavity) is disclosed.

In one aspect of the present disclosure, a method of manufacturing a semiconductor device is disclosed herein, the method comprising: filling a first insulation material made of an oxide in a trench formed in a front surface of a semiconductor substrate by growing the first insulation material on an inner surface of the trench; removing a front surface side portion of the first insulation material filled in the trench by performing a first-etching on the front surface side portion of the first insulation material; forming a cured portion by heating the semiconductor substrate in a non-oxidizing atmosphere to cure a front surface of the first insulation material that was not removed in the first-etching and remains in a deep side of the trench. An interface of portions of the first insulation. material that have been grown from both side surfaces of the trench in the filling process has a different property from the remaining portion even after the curing, and remains as a portion that is easy to be etched. The method further comprises forming a cavity in the trench on a deeper side of the cured portion by making an etchant enter into the trench from the interface to the deeper side of the cured portion to perform a second etching and removing the first insulation material remaining in the deeper side of the cured portion, the interface being present between the portions of the first insulation material that have been grown from the side surfaces of the trench in a cross sectional view of the semiconductor substrate. Wherein an opening is formed at the interface by the second etching; and closing the opening at the interface with a second insulation material.

According to the above method, an etching amount in the first etching can be adjusted to adjust a height of the front surface of the first insulation material that is to remain thereafter on the deep side of the trench, and a height of the cured portion formed by the heating (that is, a depth from the front surface of the semiconductor substrate) can be controlled. For example, the height of the cured portion can be adjusted to be located at a deep portion by making the etching amount in the first etching large. Contrary to this, the height of the cured portion can be adjusted to be closer to the front surface of the semiconductor substrate by decreasing the etching amount. In the present method, the first insulation material existing on the deeper side of the cured portion is removed by the second etching, as a result of which the cavity is formed. According to this manufacturing method, the height of the cured portion can be controlled, and a height of an upper end of the cavity to be formed on the deeper side of the cured portion (distance from the front surface of the semiconductor substrate to the cavity) can be controlled.

In another aspect of the present disclosure, a semiconductor device disclosed herein comprises a semiconductor substrate; a trench provided in the semiconductor substrate; a pair of cured portions made of a first insulation oxide material projecting inward from side surfaces of the trench at a position deeper than a front surface of the semiconductor substrate in a cross sectional view of the semiconductor substrate; and a second insulation material closing an opening provided between the pair of cured portions. A cavity is present inside the trench at a position deeper than the cured portions.

According to this configuration, since the cavity is formed at a deep position in the trench, an insulation property and a voltage resistance can be improved compared to a configuration that does not have a cavity. Further, an insulation material and/or a conductive material can be filled in the trench on a front surface side of the cured portion.

### BRIEF DESCRIPTION OF DRAWINGS

FIG. 1 is a diagram (1) explaining a manufacturing method of a semiconductor device of a first embodiment;

FIG. 2 is a diagram (2) explaining the manufacturing method of the semiconductor device of the first embodiment;

FIG. 3 is a diagram (3) explaining the manufacturing method of the semiconductor device of the first embodiment;

FIG. 4 is a diagram (4) explaining the manufacturing method of the semiconductor device of the first embodiment;

FIG. 5 is a diagram (5) explaining the manufacturing method of the semiconductor device of the first embodiment;

FIG. 6 is a diagram (6) explaining the manufacturing method of the semiconductor device of the first embodiment;

FIG. 7 is a diagram (7) explaining the manufacturing method of the semiconductor device of the first embodiment;

FIG. 8 is a diagram explaining a manufacturing method of a semiconductor device of a second embodiment;

FIG. 9 is a diagram (1) explaining a manufacturing method of a semiconductor device of a third embodiment;

FIG. 10 is a diagram (2) explaining the manufacturing method of the semiconductor device of the third embodiment;

FIG. 11 is a diagram (3) explaining the manufacturing method of the semiconductor device of the third embodiment;

FIG. 12 is a cross sectional view of the semiconductor device of the third embodiment.

### DETAILED DESCRIPTION

### First Embodiment

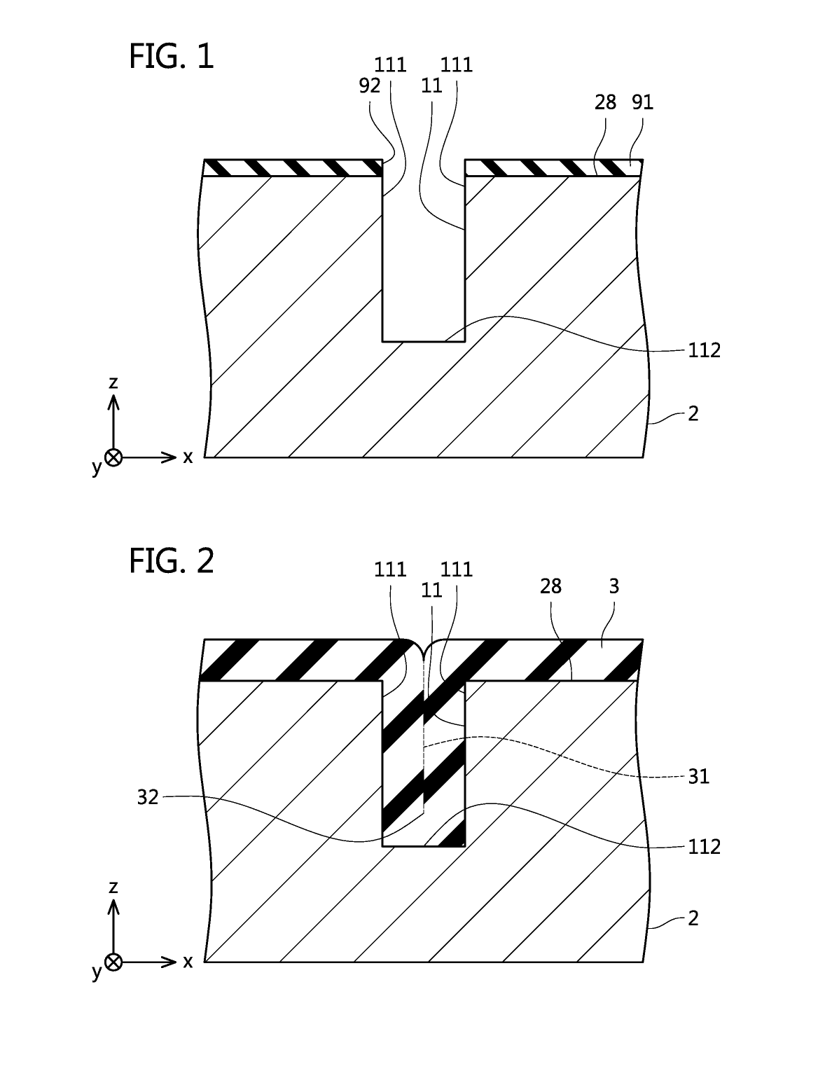

A method of manufacturing a semiconductor device of a first embodiment will be described. In the manufacturing method of the first embodiment, firstly in a cross sectional view of a semiconductor device to be manufactured as shown in FIG. 1, a mask 91 is formed on a front surface 28 of a semiconductor substrate 2, and an opening 92 is formed in the mask 91. At this stage, the semiconductor substrate 2 is exposed from the opening 92. Next, the semiconductor substrate 2 exposed from the opening 92 of the mask 91 is etched by an anisotropic etching. Due to this, a trench 11 is formed in the front surface 28 of the semiconductor substrate 2. The trench 11 comprises a bottom surface 112, and left and right side surfaces 111, 111. The semiconductor substrate 2 is formed for example of Si (silicon) or SiC (silicon carbide). The mask 91 is formed for example of TEOS (Tetraethyl Orthosilicate). In the present embodiment, the semiconductor substrate 2 is etched by an anisotropic dry etching using fluorine-based gas. The mask 91 is removed after the etching.

Next, as shown in FIG. 2, a first insulation material 3 is crystal grown on the front surface 28 of the semiconductor substrate 2 and on an inner surface of the trench 11 (both side surfaces 111, 111 and the bottom surface 112). That is, the first insulation material 3 is deposited on the front surface 28 of the semiconductor substrate 2 and on the inner surface 111, 112, 111 of the trench 11. This process is continued until the first insulation material 3 is filled inside the trench 11. It can be said as being a filling process. The first insulation material 3 is made of an oxide. In the present embodiment, TEOS is used as the first insulation material 3. The filling process is carried out by a well-known plasma CVD. The first insulation material 3 is deposited inward from the inner surface of the trench 11 (both side surfaces 111 and the bottom surface 112). Further, the first insulation material 3 piles up on the front surface 28 of the semiconductor substrate 2.

An interface 31 is generated at a portion where the first insulation material 3 deposited from one of the side surfaces 111 of the trench 11 toward an inner side of the trench 11 and the first insulation material 3 deposited from the other of the side surfaces 111 of the trench 11 toward the inner side of the trench 11 make contact. That is, the interface 31 is formed between the portions of the first insulation material 3 grown from both side surfaces 11 of the trench 11. The interface 31 between the first insulation material 3 on one side and the first insulation material 3 on the other side is formed at a center portion of the trench 11 in a width direction (x direction). The interface 31 extends in a height direction (z direction). The interface 31 extends along the side surfaces 111 of the trench 11. An end 32 of the interface 31 on a deep side is positioned above the bottom surface 112 f the trench 11. The end 32 of the interface 31 on the deep side is separated from the bottom surface 112 of the trench 11. Notably, a gap may be formed at a part of the interface 31.

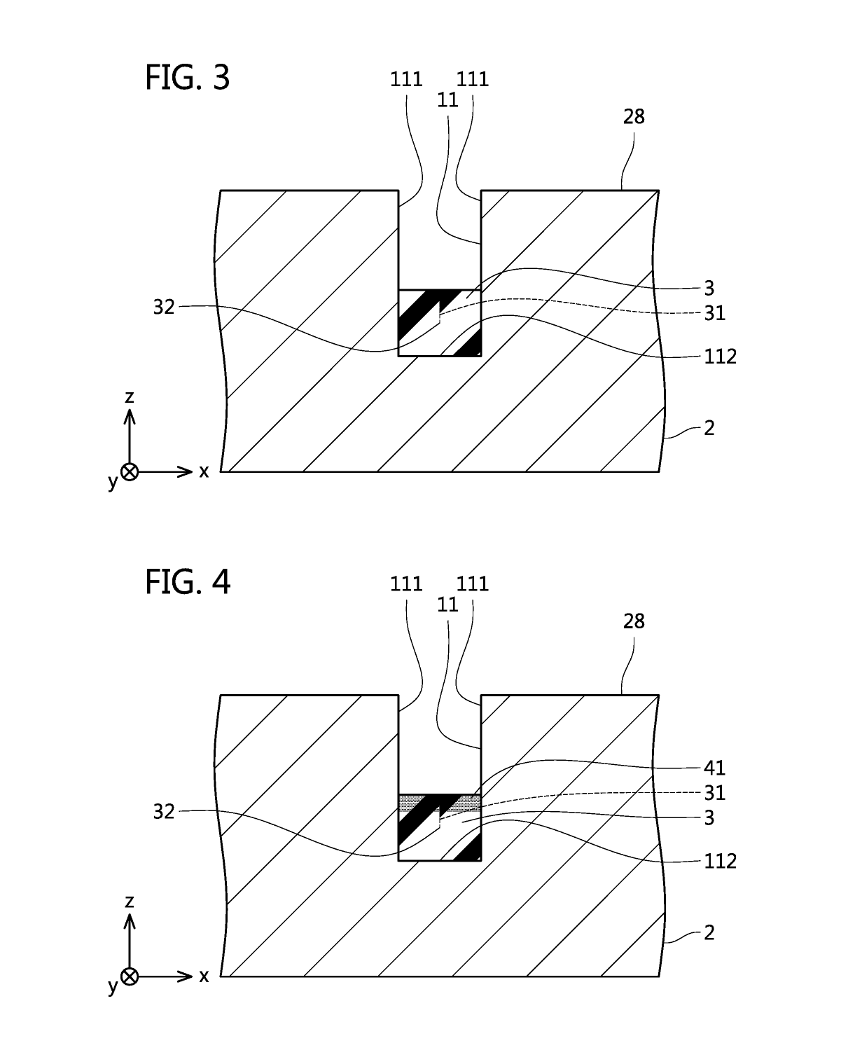

Next, as shown in FIG. 3, a part of the first insulation material 3 deposited on the semiconductor substrate 2 is removed by etching. In the present embodiment, the anisotropic dry etching using the fluorine-based gas is performed from a front surface side of the semiconductor substrate 2. The first insulation material 3 is etched from the front surface side toward the deep side. This process is continued until at least the first insulation material 3 deposited on the front surface 28 of the semiconductor substrate 2 is etched and removed. Further, it is continued until a front surface side portion of the first insulation material 3 filled in the trench 11 is removed (first etching process). An etching amount can be adjusted by adjusting an etching time. The first insulation material 3 that was not removed in the first etching process remains within the trench 11. The first etching process ends in a state where the interface 31 is still present within the first insulation material 3 remaining in the trench 11. That is, the first insulation material 3 is removed by etching the first insulation material 3 to its position above the end 32 of the interface 31 on the deep side.

Next, the semiconductor substrate 2 is heated in the state where the first insulation material 3 is remaining within the trench 11 (heating process). The heating process is carried out in a non-oxidizing atmosphere. For example, the heating process is carried out under N₂ (nitrogen) atmosphere or Ar (argon) atmosphere. When the first insulation material 3 is heated under the non-oxidizing atmosphere, a front surface of the first insulation material 3 is cured, and a cured portion 41 is formed. When the heating is carried out in the non-oxidizing atmosphere, the portions of the first insulation material 3 that are separated by the interface 31 are suppressed from binding to each other. As a result, the interface 31 remains in the cured portion 41 as well.

In the present embodiment, a heating temperature is set to 1000° C., and a heating time is set to 30 minutes. As a result of heating the first insulation material 3, an upper portion of the first insulation material 3 shrinks and hardens, and becomes densified. Due to this, the cured portion 41 is formed on the front surface of the first insulation material 3. The densification does not take place satisfactorily at the interface 31. As a result, the interface 31 remaining in the cured portion 41 becomes a weak point in a second etching process to be described later. The interface 31 remaining in the cured portion 41 will become an entrance portion for an etchant. An etching rate at the interface 31 of the cured portion 41 is higher than an etching rate for the cured portion 41 other than the interface 31.

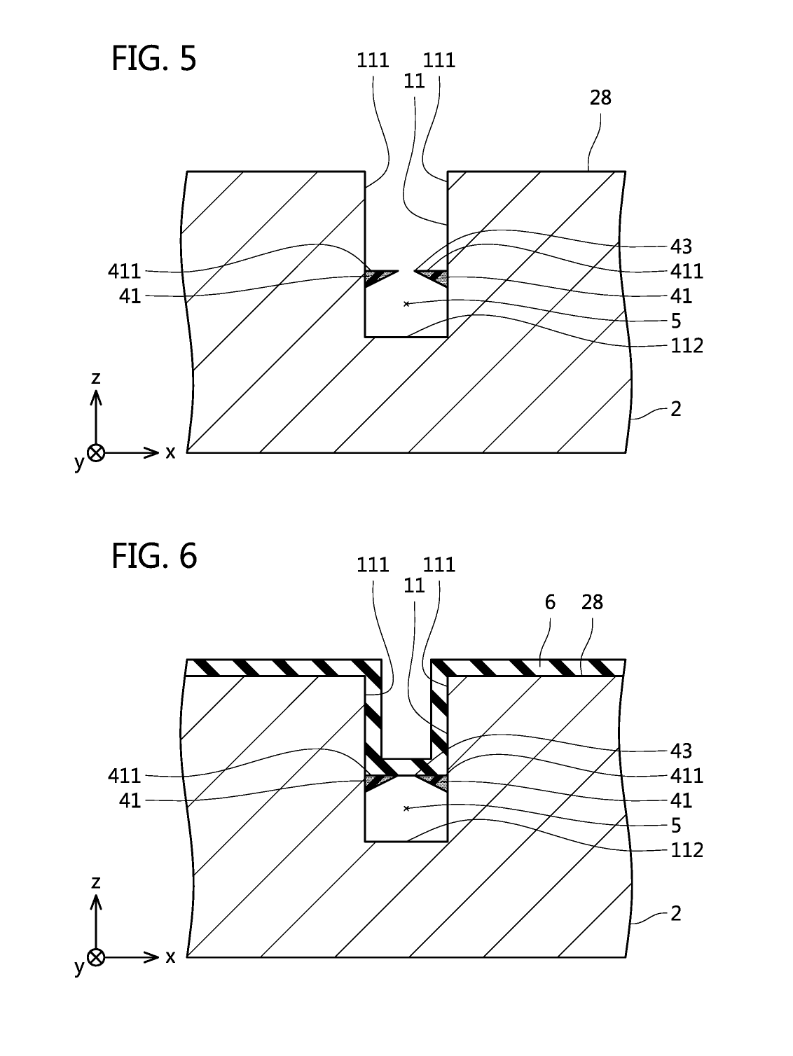

Next, as shown in FIG. 5, a part of the first insulation material 3 remaining in the trench 11 is removed by etching (second etching process). More specifically, an etchant is introduced into the trench 11 where the first insulation material 3 remains present. The etchant is introduced toward the first insulation material 3, and the etchant is caused to enter to a deeper side of the cured portion 41 from the interface 31 of the first insulation material 3. An etching rate of the portion of the first insulation material 3 that has not been cured is higher than an etching rate of the cured portion 41. The etchant enters into the first insulation material 3 on the deeper side of the cured portion 41. Due to this, the first insulation material 3 on the deeper side of the cured portion 41 is etched and removed. The first insulation material 3 is removed to form a cavity 5 inside the trench 11 on the deeper side of the cured portion 41. A dielectric constant of the cavity 5 is smaller than a dielectric constant of the first insulation material 3.

In the present embodiment, an isotropic wet etching is performed using a diluted HF (hydrofluoric acid). The first insulation material 3 is etched by the isotropic etching with the interface 31 formed in the cured portion 41 as the entrance portion for the etchant. The first insulation material 3 on the deeper side of the cured portion 41 is etched from the interface 31 toward its surroundings. In the present embodiment, the etching time is set to 200 seconds.

The etching is suppressed at a greater degree in the cured portion 41 of the first insulation material 3 than any other portion thereof. The cured portion 41 is in part removed by the etching, and other parts thereof remains without being etched. A pair of cured portions 41 remain within the trench 11. One cured portion 41 protrudes from each of the side surface 111 on the one side and the side surface 111 on the other side of the trench 11. The cured portions 41 protrude from the side surfaces 111 of the trench 11 toward an inner side of the trench 11. In the second etching process, the interface 31 formed in the cured portion 41 is opened upon when the etchant enters into the interface 31, and an opening 43 is thereby formed. The opening 43 is formed between the one cured portion 41 and the other cured portion 41. The opening 43 communicates a space in the trench on a front surface side of the cured portion 41 and the cavity 5 on the deeper side thereof.

Next, as shown in FIG. 6, the second insulation material 6 is thinly deposited on the front surface of the semiconductor substrate 2 and on the inner surface of the trench 11. More specifically, the second insulation material 6 is grown from the front surface 28 of the semiconductor substrate 2, the both side surfaces 111, 111 of the trench 11, and front surfaces 411, 411 of the cured portion 41. At this occasion, portions of the second insulation material 6 growing from the front surfaces 411, 411 of the cured portion 41 connect to each other, and closes the opening 43 (closing process). The film of the second insulation material 6 covers the opening 43. The film of the second insulation material 6 seals the cavity 5 on the deeper side of the cured portion 41. The film of the second insulation material 6 covers the front surfaces 411, 411 of the cured portion 41 and the both side surfaces 111, 111 of the trench 11. The second insulation material 6 is made of an oxide. In the present embodiment, TEOS is used as the second insulation material 6. The second insulation material 6 is of the same material as the first insulation material 3. The second insulation material 6 may be a different material from the first insulation material 3. The closing process is carried out by the well-known plasma CVD, for example.

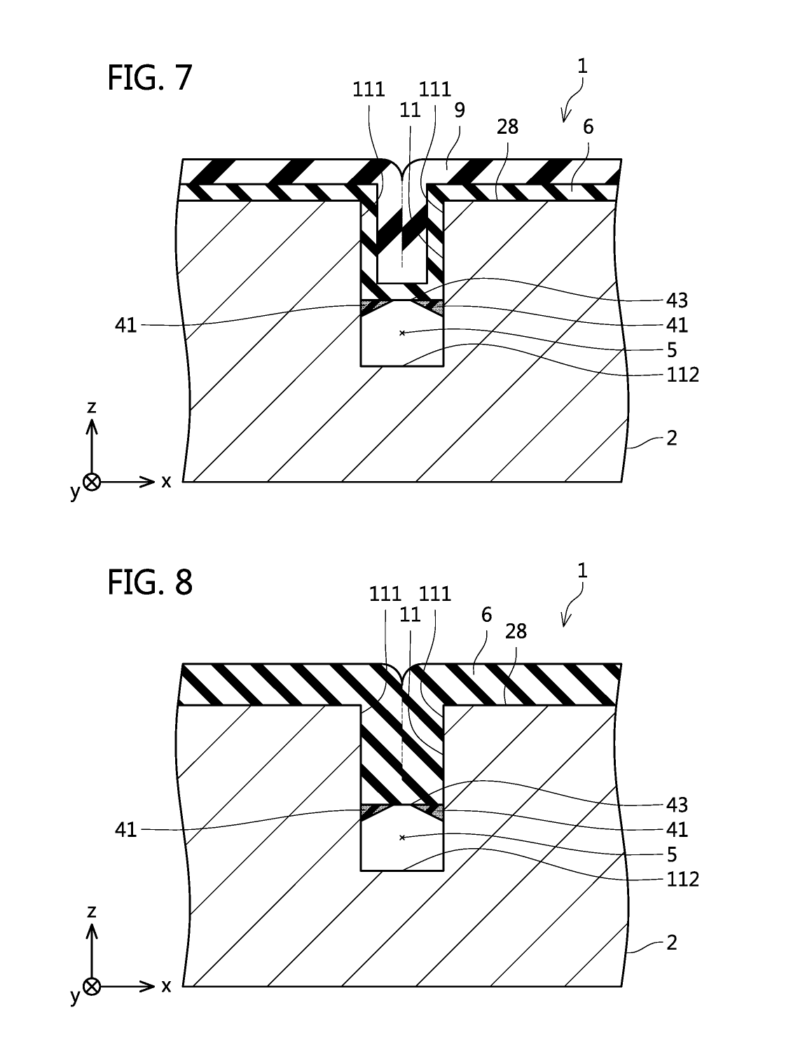

As shown in FIG. 7, a third insulation material 9 is grown on a front surface of the thin film of the second insulation material 6. Due to this, the third insulation material 9 is filled in the trench 11 on an inner side of the film of the second insulation material 6 (third insulation material filling process). The third insulation material 9 is made of an oxide. The third insulation material filling process is carried out by the well-known plasma CVD, for example. In the present embodiment, TEOS is used as the third insulation material 9.

The semiconductor device I manufactured by the above manufacturing method comprises the semiconductor substrate 2, and the trench 11 provided in the front surface 28 of the semiconductor substrate 2. Further, the semiconductor device I comprises the pair of cured portions 41, 41 configured of the first oxide insulation material 3 and protruding toward the inside of the trench 11 from the both side surfaces 111, 111 of the trench 11 at a deeper position than the front surface 28 of the semiconductor substrate 2. Further, the semiconductor device 1 comprises the second insulation material 6 that closes the opening 43 provided between the pair of cured portions 41. The cavity 5 is provided inside the trench 11 on the deeper side of the cured portion 41.

As is apparent from the above description, according to the above manufacturing method, a removal amount of the first insulation material 3 can be adjusted by adjusting the etching amount in the first etching process. Due to this, an amount of the first insulation material 3 to remain within the trench 11 after the etching can be adjusted, so the height of the front surface of the first insulation material 3 can be controlled. For example, the height of the front surface of the first insulation material 3 can be located at a deep portion by making the etching amount large. By making the etching amount small, the height of the front surface of the first insulation material 3 can be adjusted to be closer to the front surface 28 of the semiconductor substrate 2. As a result, a height of the cured portion 41 formed on the front surface of the first insulation material 3 in the heating process can be controlled, and a front surface-side height of the cavity 5 provided on the deeper side of the cured portion 41 (distance between the front surface 28 of the semiconductor substrate 2 and the cavity 5) can be controlled.

As above, according to the above manufacturing method, the front surface-side height of the cavity 5 to be remained within the trench 11 can be controlled. Further, by controlling a size or the height of the cavity 5, the insulation property within the trench 11 can be controlled.

Further, in the above semiconductor device 1, the cavity 5 is formed within the trench 11 on the deeper side of the cured portion 41. According to this configuration, since the dielectric constant of the cavity 75 is smaller than the dielectric constant of the first insulation material 3, the insulation property within the trench 11 can be increased by providing the cavity 5 inside the trench 11 than in a case Where no cavity 5 is present.

As above, an embodiment has been described, however, the specific configuration is not limited to this embodiment In the description below, configurations similar to the configurations in the above description will be given the same reference signs, and the description thereof will be omitted.

### Second Embodiment

In the above embodiment, the second insulation material 6 was deposited thinly within the trench 11, however, no limitation is made to this configuration. In a second embodiment, as shown in FIG. 8, the second insulation material 6 may be deposited thickly in succession to the closing process. The second insulation material 6 may be filled over an entire portion above the cured portion 41 within the trench 11 (second insulation material filling process). That is, the second insulation material 6 is further filled in the trench 11 on the inner side of the film of the second insulation material 6. According to this method, the closing process and the second insulation material filling process can be carried out in succession, so the second insulation material 6 can be filled quickly within the trench 11. The closing process and the second insulation material filling process can be carried out as one process.

### Third Embodiment

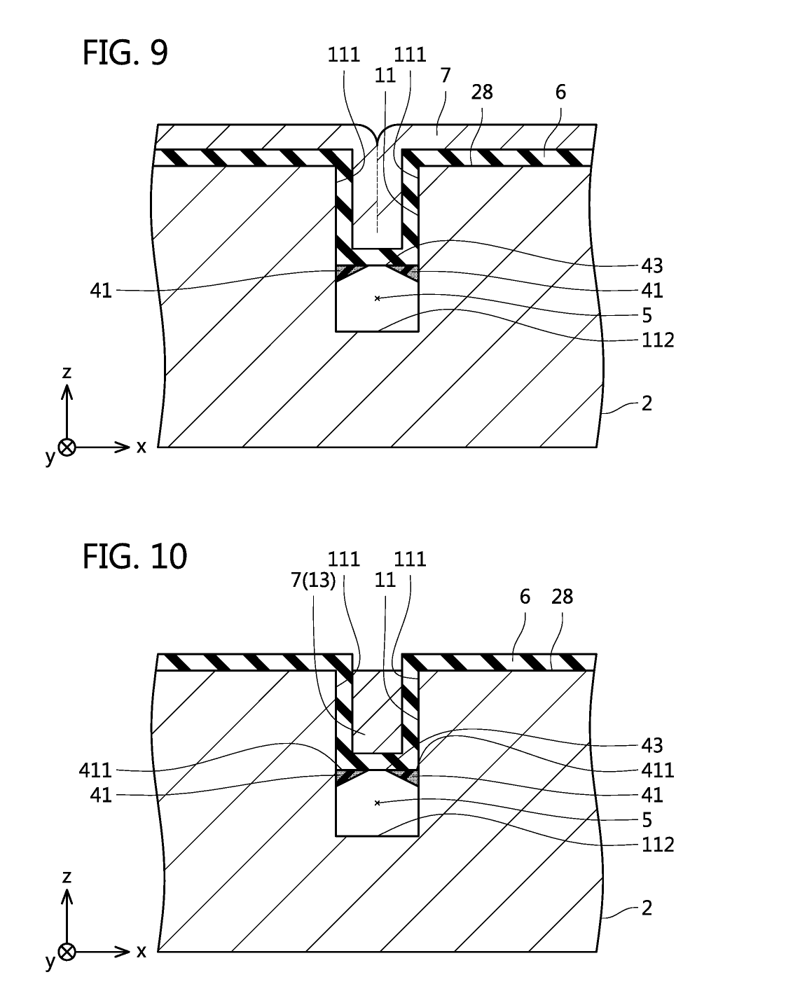

A manufacturing method of a semiconductor device of a third embodiment will be described. In the above first embodiment, the third insulation material 9 was filled M the trench 11 after the closing process, however, no limitation is made to this configuration. In the third embodiment, as shown in FIG. 9, a conductive material 7 (material that is to become a gate electrode) is filled in the trench 11 after the closing process (gate electrode filling process). The conductive material 7 is gown on the front surface of the film of the second insulation material 6. In the present embodiment, polysilicon (Poly Si) is used as the conductive material 7. The gate electrode is formed by the conductive material 7 being deposited within the trench 11.

Next, as shown in FIG. 10, a part of the conductive material 7 deposited on the front surface of the second insulation material 6 is removed by etching (third etching process). In the present embodiment, the anisotropic dry etching using the fluorine-based gas is performed. The conductive material 7 is etched from the front surface side toward the deep side. The conductive material 7 deposited on the front surface of the second insulation material 6 is removed by etching. The conductive material 7 filled within the trench 11 is left to remain therein without being etched. The gate electrode 13 is formed by the conductive material 7 remaining within the trench 11.

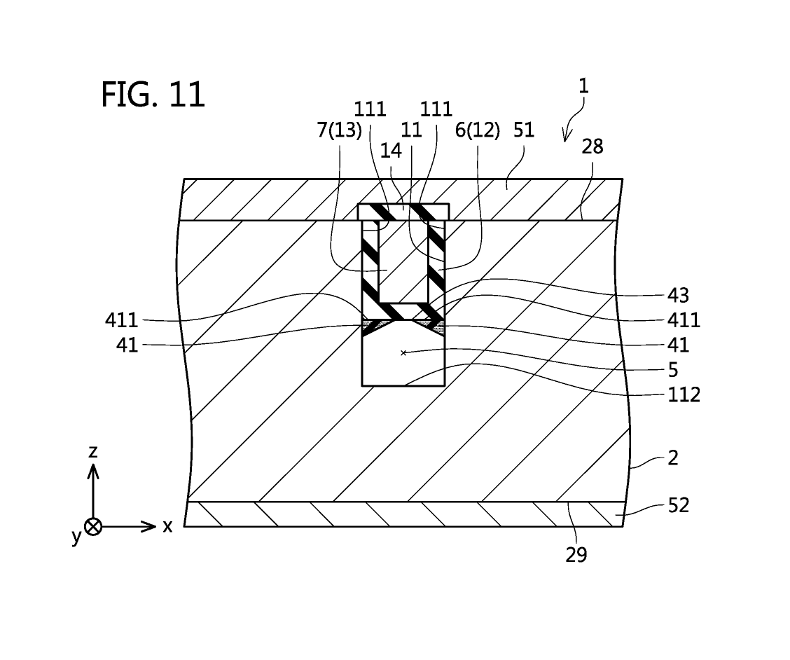

Next, as shown in FIG. 11, an unnecessary portion of the second insulation material 6 is etched and removed. A gate insulating film 12 is formed by the film of the second insulation material 6. Further, an interlayer insulating film 14 is formed on the front surface side of the gate electrode 13. The interlayer insulating film 14 covers the gate electrode 13. Further, a front surface electrode 51 is formed on the front surface 28 of the semiconductor substrate 2. Further, a rear surface electrode 52 is formed on a rear surface 29 of the semiconductor substrate 2. The semiconductor device 1 can be manufactured by the above manufacturing method.

According to the above manufacturing method, an insulation property between the gate electrode 13 and the semiconductor substrate 2 can be controlled by controlling the size of the cavity 5. Further, by fanning the cavity 5, a voltage resistance of the semiconductor device can be improved than in the case where no cavity 5 is present. Further, an abnormality in a shape of an insulation portion between the gate electrode 13 and the semiconductor substrate 2 can be suppressed.

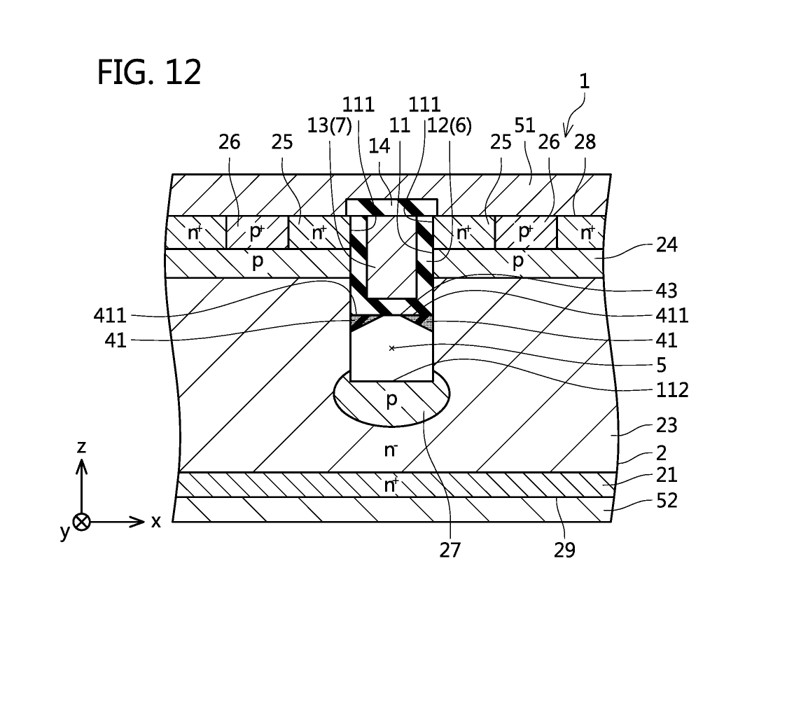

Next, an example of the semiconductor device 1 will be described. As shown in FIG. 12, the semiconductor device 1 comprises the semiconductor substrate 2, the front surface electrode 51 covering the front surface 28 of the semiconductor substrate 2, and the rear surface electrode 52 covering the rear surface 29 of the semiconductor substrate 2. Further, the semiconductor device 1 comprises the trench 11 provided in the front surface 28 of the semiconductor substrate 2, and the pair of cured portions 41, 41 protruding toward the inner side of the trench 11 from the both side surfaces 111 of the trench 11. The cavity 5 is provided inside the trench 11 on the deep side of the cured portions 41, 41.

A semiconductor element is provided in the semiconductor substrate 2. In the present embodiment, a MOSFET (Metal Oxide Semiconductor Field Effect Transistor) is provided in the semiconductor substrate 2. The semiconductor substrate 2 comprises a drain region 21, a drift region 23, a base region 24, a source region 25, and a contact region 26 in this order from a rear surface 29 side toward a front surface 28 side. Further, a floating region 27 is provided in the semiconductor substrate 2.

The drain region 21 is a p-type region. The drain region 21 has a high impurity concentration. The drain region 21 is provided on the rear surface side of the drift region. 23. The drain region 21 is provided in a range exposed to the rear surface 29 of the semiconductor substrate 2. The drain region 21 is configured to electrically connect to the rear surface electrode 52.

The drift region 23 is an n-type region. An impurity concentration of the drift region 23 is lower than the impurity concentration of the drain region 21. The drift region 23 is provided on the front surface side of the drain region 21. The drift region 23 is provided between the drain region 21 and the base region 24.

The base region 24 is a p-type region. The base region 24 is provided on the front surface side of the drift region 23. The base region 24 is provided between the drift region 23 and the source region 25 and contact region 26. The base region 24 is provided in a range in contact with the trench 11. The base region 24 is provided at a position higher than the cured portions 41,41.

The source region 25 is an n-type region. An impurity concentration of the source region 25 is higher than the impurity concentration of the drift region 23. The source region 25 is provided on the front surface side of the base region 24. The source region 25 is provided in a range in contact with the trench 11. The source region 25 is provided in an island shape in a range exposed to the front surface 28 of the semiconductor substrate 2. The source region 25 is configured to electrically connect to the front surface electrode 51.

The contact region 26 is a p-type region. An impurity concentration of the contact region 26 is higher than the impurity concentration of the base region 24. The contact region 26 is provided on the front surface side of the base region 24. The contact region 26 is arranged at a position different form the source region 25. The contact region 26 is provided in an island shape in a range exposed to the front surface 28 of the semiconductor substrate 2. The contact region 26 is configured to electrically connect to the front surface electrode 51.

The floating region 27 is a p-type region. An impurity concentration of the floating region 27 is lower than the impurity concentration of the contact region 26. The floating region 27 is provided within the drift region 23. The floating region 27 is provided around a bottom of the trench 11 The floating region 27 is provided in a range in contact with the both side surfaces 111, 111 and the bottom surface 112 of the trench 11. The floating region 27 is arranged at a position on the deeper side of the cured portions 41. A potential of the floating region 27 is in a floating state.

The trench 11 extends from the front surface 28 of the semiconductor substrate 2 toward the deep side (in a z direction). The trench 11 penetrates the source region 25 and the base region 24 from the front surface 28 of the semiconductor substrate 2 to a depth that reaches the drill region 23. The gate insulating film 12 is provided on the inner surface of the trench 11. The gate electrode 13 is provided inside the trench 11.

The pair of cured portions 41, 41 is provided in the trench 11 at a position on the deeper side of the front surface 28. The opening 43 is provided in between the pair of cured portions 41, 41.

The gate insulating film 12 is the film of the second insulation material 6. The gate insulating film 12 is made for example of TEOS. The gate insulating film 12 covers the front surfaces 411, 411 of the cured portions 41 and the both side surfaces 111, 111 of the trench 11. The gate insulating film 12 closes the opening 43. The gate insulating film 12 seals the cavity 5. The gate insulating film 12 is provided between the semiconductor substrate 2 and the gate electrode 13.

The gate electrode 13 is configured of the conductive material 7 filled in the trench 11. The gate electrode 13 is made for example of polysilicon (Poly Si). The gate electrode 13 is filled in the trench 11 on the inner side of the gate insulating film 12 (film of the second insulation material 6). The gate electrode 13 is insulated from the semiconductor substrate 2 by the gate insulating film 12. The interlayer insulating film 14 is provided on the gate electrode 13.

The interlayer insulating film 14 is made for example of silicon oxide (SiO₂). The interlayer insulating film 14 covers the front surface of the gate electrode 13. The interlayer insulating film 14 insulates the gate electrode 13 from the front surface electrode 51.

The front surface electrode 51 has a conductivity. The front surface electrode 51 is made for example by using one or more of aluminum (Al), nickel (Ni), gold (Au), and the like. The front surface electrode 51 covers the front surface 28 of the semiconductor substrate 2 and the interlayer insulating film 14. A terminal (not shown) is connected via solder onto a front surface of the front surface electrode 51.

The rear surface electrode 52 has a conductivity. The rear surface electrode 52 is made for example by using one or more of aluminum (Al), nickel (Ni), gold (Au), and the like. The rear surface electrode 52 covers the rear surface 29 of the semiconductor substrate 2. A terminal (not Shown) is connected via solder onto a rear surface of the rear surface electrode 52.

According to the above semiconductor device 1, due to the cavity 5 being provided on the deeper side of the gate electrode 13, the insulation property between the gate electrode 13 and the semiconductor substrate 2 can be improved than in the case where no cavity 5 is present. Further, when the p-type floating region 27 is provided in the semiconductor substrate 2 surrounding the bottom of the trench 11, the voltage resistance of the MOS is improved. In the present embodiment, in addition to the above, the voltage resistance of the MOS is further improved due to the cavity 5 being provided between the bottom surface of the gate electrode 13 and the bottom surface of the trench 11. The combination of the cavity 5 and the floating region 27 can significantly improve the voltage resistance of the MOS.

Specific examples of the present disclosure have been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

Some of the features characteristic to below-described embodiments will herein be listed. It should be noted that the respective technical elements are independent of one another, and are useful solely or in combinations.

1. The closing may comprise growing a film of the second insulation material on a front surface of the cured portion and the side surfaces of the trench, and the method may further comprise in succession to the closing, filling the second insulation material in the trench on an inner side of the film.

According to this configuration, the closing process and the second insulation material filling process can be carried out as one process, and a process number can be reduced.

2. The closing may comprise growing a film of the second insulation material on a front surface of the cured portion and the side surfaces of the trench, and the method may further comprise, after the closing, filling a third insulation material in the trench on an inner side of the film.

According to this configuration, a freedom of selection of material can be increased by filling the third insulation material on the inner side of the second insulation material.

3. The closing may comprise growing a film of the second insulation material on a front surface of the cured portion and the side surfaces of the trench, and the method may further comprise, after the closing, filling a material that is to become a gate electrode in the trench on an inner side of the film.

According to this configuration, the gate electrode can be arranged on the front surface side and the cavity can be arranged on the deep side within the trench.

4. In the semiconductor device, front surfaces of the pair of cured portions and the side surfaces of the trench may be covered by a film of the second insulation material. A gate electrode may be filled in the trench on an inner side of the film. A p-type floating region may be provided in the semiconductor substrate around a bottom of the trench.

According to this configuration, since the cavity is provided on the deeper side of the gate electrode within the trench, the insulation property between the gate electrode and the semiconductor substrate can be improved. The combination of the p-type floating region and the cavity improves the voltage resistance of the semiconductor device.

What is claimed is:

1. A method of manufacturing a semiconductor device, the method comprising:
filling a first insulation material made of an oxide in a trench formed in a front surface of a semiconductor substrate by growing the first insulation material on an inner surface of the trench;
removing a front surface side portion of the first insulation material filled in the trench by performing a first-etching on the front surface side portion of the first insulation material;
forming a cured portion by heating the semiconductor substrate in a non-oxidizing atmosphere to cure a front surface of the first insulation material that was not removed in the first-etching and remains in a deep side of the trench;
forming a cavity in the trench on a deeper side of the cured portion by making an etchant enter into the trench from an interface to the deeper side of the cured portion to perform a second-etching and removing the first insulation material remaining in the deeper side of the cured portion, the interface being present between portions of the first insulation material that have been grown from side surfaces of the trench in a cross sectional view of the semiconductor substrate, wherein an opening is formed at the interface by the second etching; and
closing the opening at the interface with a second insulation material.

2. The method according to claim 1, wherein
the closing comprises growing a film of the second insulation material on a front surface of the cured portion and the side surfaces of the trench,
the method further comprising:
in succession to the closing, filling the second insulation material in the trench on an inner side of the film.

3. The method according to claim 1, wherein
the closing comprises growing a film of the second insulation material on a front surface of the cured portion and the side surfaces of the trench,
the method thither comprising:
after the closing, filling a third insulation material in the trench on an inner side of the film.

4. The method according to claim 1, wherein
the closing comprises growing a film of the second insulation material on a front surface of the cured portion and the side surfaces of the trench,
the method further comprising
after the closing, filling a material that is to become a gate electrode in the trench on an inner side of the film.

5. A semiconductor device comprising:
a semiconductor substrate;
a trench provided in the semiconductor substrate;
a pair of cured portions made of a first insulation oxide material projecting inward from side surfaces of the trench at a position deeper than a front surface of the semiconductor substrate in a cross sectional view of the semiconductor substrate; and
a second insulation material closing an opening provided between the pair of cured portions,
wherein
a cavity is present inside the trench at a position deeper than the cured portions.

6. The semiconductor device according to claim 5, wherein
front surfaces of the pair of cured portions and the side surfaces of the trench are covered by a film of the second insulation material,
a gate electrode is filled in the trench on an inner side of the film, and
a p-type floating region is provided in the semiconductor substrate around a bottom of the trench.
